(19) United States
(12) Patent Application Publication
(10) Pub. No.: US 2018/0203625 A1
(43) Pub. Date: Jul. 19, 2018

(54) STORAGE SYSTEM WITH MULTI-DIMENSIONAL DATA PROTECTION MECHANISM AND METHOD OF OPERATION THEREOF

(71) Applicant: CNEX LABS, Inc., San Jose, CA (US)

(72) Inventors: Xiaojie Zhang, Saratoga, CA (US); Pengfei Huang, San Diego, CA (US)

(21) Appl. No.: 15/410,528

(22) Filed: Jan. 19, 2017

(51) Int. Cl. G06F 3/06; H03M 13/45; H03M 13/00

(52) U.S. Cl. CPC G06F 3/0622; G06F 3/0623; G06F 3/064; H03M 13/611; G06F 3/0683; H03M 13/45; G06F 3/0659

(57) ABSTRACT

A storage system includes: a data storage system, configured to: load a user data block in a user data array, and link a column protection and a row protection with the user data array; and a non-volatile storage device, coupled to the data storage system, configured to store the user data block linked to the column protection and the row protection.

### TECHNICAL FIELD

An embodiment of the present invention relates generally to a storage system, and more particularly to a system for data protection.

### BACKGROUND

Social media has become a massive generator of user data. The storage, transfer, and retrieval of text messages, videos, songs, movies, and e-books presents difficult challenges for data centers. Storing and retrieving large amounts of data becomes more problematic as storage media wears and data becomes corrupted. As data storage transitions from magnetic media to semiconductor non-volatile memory, the data protection processes can be time consuming and consume additional capacity in order to preserve the stored data for extended periods of time.

Thus, a need still remains for a storage system with multi-dimensional data protection mechanism to provide improved data reliability and recovery. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides an apparatus, including a data storage system, configured to: load a user data block in a user data array, and link a column protection and a row protection with the user data array; and a non-volatile storage device, coupled to the data storage system, configured to store the user data block linked to the column protection and the row protection.

An embodiment of the present invention provides a method including loading a user data block in a user data array; linking a column protection and a row protection with the user data array; and storing the user data block linked to the column protection and the row protection.

An embodiment of the present invention provides a non-transitory computer readable medium including: loading a user data block in a user data array; linking a column protection and a row protection with the user data array; and storing the user data block linked to the column protection and the row protection.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a storage system with data protection enhancement mechanism in an embodiment of the present invention.

FIG. 2 depicts an example architectural view of the multi-dimensional data protection mechanism in an embodiment.

FIG. 3 is an exemplary stopping set of error bits in a user data array in an embodiment.

FIG. 4 is a flow chart of an adaptive bit flipping algorithm of the data protection enhancement mechanism in an embodiment.

FIG. 5 is a graph of a probability of data bit voltage across a voltage range.

FIG. 6 is a graph depicting an example improvement of the raw bit error rate in an embodiment of the present invention.

FIG. 7 is a flow chart of a method of operation of a storage system in an embodiment of the present invention.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The term “module” referred to herein can include software, hardware, or a combination thereof in an embodiment of the present invention in accordance with the context in which the term is used. For example, the software can be machine code, firmware, embedded code, and application software. Also for example, the hardware can be circuitry, processor, computer, integrated circuit, integrated circuit cores, a pressure sensor, an inertial sensor, a microelectromechanical system (MEMS), passive devices, or a combination thereof. The term “multi-dimensional” referred to herein can include 2-dimensional, 3-dimensional, or N-dimensional arrays for processing the multi-dimensional data protection mechanism without limitation.

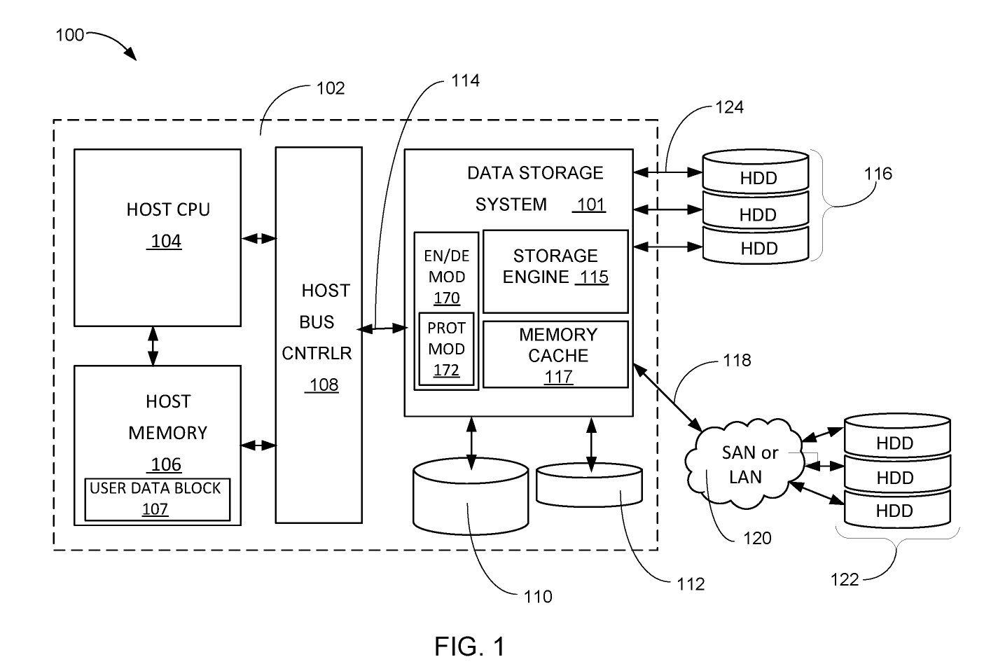

Referring now to FIG. 1, therein is shown a storage system 100 with multi-dimensional data protection mechanism in an embodiment of the present invention. The storage system 100 is depicted in FIG. 1 as a functional block diagram of the storage system 100 with a data storage system 101. The functional block diagram depicts the data storage system 101 installed in a host computer 102.

As an example, the host computer 102 can be as a server or workstation. The host computer 102 can include at least a host central processing unit 104, host memory 106 coupled to the host central processing unit 104, and a host bus controller 108. The host bus controller 108 provides a host interface bus 114, which allows the host computer 102 to utilize the data storage system 101. The host memory 106 can contain a user data block 107 that can be transferred to or retrieved from the data storage system 101.

It is understood that the function of the host bus controller 108 can be provided by host central processing unit 104 in some implementations. The host central processing unit 104 can be implemented with hardware circuitry in a number of different manners. For example, the host central processing unit 104 can be a processor, an application specific integrated circuit (ASIC) an embedded processor, a microprocessor, a hardware control logic, a hardware finite state machine (FSM), a digital signal processor (DSP), or a combination thereof.

The data storage system 101 can be coupled to a solid state disk 110, such as a non-volatile memory based storage device having a peripheral interface system, or a non-volatile memory 112, such as an internal memory card for expanded or extended non-volatile system memory.

The data storage system 101 can also be coupled to non-volatile storage devices 116, such as hard disk drives (HDD) or solid state disks (SSD) that can be mounted in the host computer 102, external to the host computer 102, or a combination thereof. The solid state disk 110, the non-volatile memory 112, and the non-volatile storage devices 116 can be considered as direct attached storage (DAS) devices, as an example.

The data storage system 101 can also support a network attach port 118 for coupling a network 120. Examples of the network 120 can be a local area network (LAN) and a storage area network (SAN). The network attach port 118 can provide access to network attached storage (NAS) devices 122.

While the network attached storage devices 122 are shown as hard disk drives, this is an example only. It is understood that the network attached storage devices 122 could include magnetic tape storage (not shown), and storage devices similar to the solid state disk 110, the non-volatile memory 112, or the non-volatile storage devices 116 that are accessed through the network attach port 118. Also, the network attached storage devices 122 can include just a bunch of disks (JBOD) systems or redundant array of intelligent disks (RAID) systems as well as other network attached storage devices 122.

The data storage system 101 can be attached to the host interface bus 114 for providing access to and interfacing to multiple of the direct attached storage (DAS) devices via a cable 124 for storage interface, such as Serial Advanced Technology Attachment (SATA), the Serial Attached SCSI (SAS), or the Peripheral Component Interconnect-Express (PCI-e) attached storage devices.

The data storage system 101 can include a storage engine 115 and memory devices 117. The storage engine 115 can be implemented with hardware circuitry, software, or a combination thereof in a number of ways. For example, the storage engine 115 can be implemented as a processor, an application specific integrated circuit (ASIC) an embedded processor, a microprocessor, a hardware control logic, a hardware finite state machine (FSM), a digital signal processor (DSP), or a combination thereof.

The storage engine 115 can control the flow and management of data to and from the host computer 102, and to and from the direct attached storage (DAS) devices, the network attached storage devices 122, or a combination thereof. The storage engine 115 can also perform data reliability check and correction, which will be further discussed later. The storage engine 115 can also control and manage the flow of data between the direct attached storage (DAS) devices and the network attached storage devices 122 and amongst themselves. The storage engine 115 can be implemented in hardware circuitry, a processor running software, or a combination thereof.

For illustrative purposes, the storage engine 115 is shown as part of the data storage system 101, although the storage engine 115 can be implemented and partitioned differently. For example, the storage engine 115 can be implemented as part of in the host computer 102, implemented partially in software and partially implemented in hardware, or a combination thereof. The storage engine 115 can be external to the data storage system 101. As examples, the storage engine 115 can be part of the direct attached storage (DAS) devices described above, the network attached storage devices 122, or a combination thereof. The functionalities of the storage engine 115 can be distributed as part of the host computer 102, the direct attached storage (DAS) devices, the network attached storage devices 122, or a combination thereof.

The memory devices 117 can function as a local cache to the data storage system 101, the storage system 100, or a combination thereof. The memory devices 117 can be a volatile memory or a nonvolatile memory. Examples of the volatile memory can be static random access memory (SRAM) or dynamic random access memory (DRAM).

The storage engine 115 and the memory devices 117 enable the data storage system 101 to meet the performance requirements of data provided by the host computer 102 and store that data in the solid state disk 110, the non-volatile memory 112, the non-volatile storage devices 116, or the network attached storage devices 122.

For illustrative purposes, the data storage system 101 is shown as part of the host computer 102, although the data storage system 101 can be implemented and partitioned differently. For example, the data storage system 101 can be implemented as a plug-in card in the host computer 102, as part of a chip or chipset in the host computer 102, as partially implement in software and partially implemented in hardware in the host computer 102, or a combination thereof. The data storage system 101 can be external to the host computer 102. As examples, the data storage system 101 can be part of the direct attached storage (DAS) devices described above, the network attached storage devices 122, or a combination thereof. The data storage system 101 can be distributed as part of the host computer 102, the direct attached storage (DAS) devices, the network attached storage devices 122, or a combination thereof.

The storage system 100 can include and utilize an encoding and decoding mechanism for processing information. The storage system 100 can encode the information prior to storage. The storage system 100 can decode the stored data for accessing the information. The storage system 100 can utilize the encoding and decoding mechanism to detect, correct, or a combination for errors. The storage system 100 can further utilize the encoding and decoding mechanism for data compression, cryptography, communication, or a combination thereof.

The storage system 100 can utilize an encode-decode module 170. The encode-decode module 170 is a circuit, a device, a method, a system, a process, or a combination thereof for converting data from one form to another.

The encode-decode module 170 can be used to encode intended or targeted data for providing error protection, error detection, error correction, redundancy, or a combination thereof. The encode-decode module 170 can be used to decode received or accessed data to recover the intended or target data based on error detection, error correction, redundancy, or a combination of processes thereof.

The encode-decode module 170 can be based on a standard, an algorithm, or a combination thereof predetermined by or known to the storage system 100. For example, the storage system 100 can utilize linear codes, such as including linear block codes or convolutional codes.

As a more specific example, the storage system 100 can utilize error detection or correction codes such as cyclic codes, repetition codes, parity codes, polynomial codes, geometric codes, block codes, algebraic codes, probabilistic codes, or a combination thereof. Also as a more specific example, the storage system 100 can utilize the encode-decode module 170 including RAID parity, a Bose, Chaudhuri, and Hocquenghem (BCH) codeword, a Reed-Solomon (RS) code, a low-density parity check code (LDPC), BSPP soft bit flipping, or a combination thereof for maintaining data integrity within a target bit error rate.

By way of an example, the encode-decode module 170 is shown as part of the data storage system 101 but can be included in, integral with, or a combination thereof for the host computer 102 or a portion or circuit therein, the solid state disk 116, the network attached storage devices 122, or a combination thereof. For illustrative purposes, the storage system 100 will be described as utilizing a protection module 172, such as a BCH encoding module, RS encoding module, LDPC encoding module, or a RAID parity module. However, it is understood that the storage system 100 can utilize any other type of coding mechanism as described above.

Also for illustrative purposes, the storage system 100 will be described as utilizing the coding mechanism in storing and accessing information with NAND flash memory. However, it is understood that the storage system 100 can utilize the coding mechanism with other types of memory, such as volatile memory, other types of flash or non-volatile memory, or a combination thereof. The storage system 100 can further utilize the coding mechanism with other applications, such as communication or cryptography, as discussed above.

In NAND flash storage, the basic unit of NAND read can be a page, whose size can be fixed throughout its lifetime. The size of a NAND flash page can usually be 8 KB or 16 KB, along with some extra space that can be called “spare space”, and can be generally used for storing meta-data and error correction code (ECC) redundancy. The amount of user data stored per page can be fixed, such as for 8 KB, 16 KB, or other size depending on the NAND flash physical size specification.

The spare space that can be used for ECC parities can also be fixed. For the same type of ECC, the code rate, or the ratio of its information size to its code length known as information size plus parity size, determines its error correction power. Generally speaking, with larger parity, more bits can be corrected using an ECC codeword. Therefore, when ECC codewords, including both user data and parities, are stored in a single NAND flash page, the correction power provided by the ECC can be fixed throughout the lifetime of the NAND.

However, the characteristic of NAND flash can lead to the number of error bits increasing as the number of program/erase (P/E) cycles increases. In other words, in order to increase the reliability of NAND flash at or towards its end of lifetime or to extend its lifetime, stronger ECC that can correct more error bits can be required as P/E cycles increases.

The storage system 100 can utilize extra or additional coding mechanism in addition to and in combination with other coding mechanism. The storage system 100 can utilize ECC codewords whose parities can be divided and stored in separate places while remaining linked to the codewords generated from the user data block 107. The storage system 100 can store part of the ECC parity in the same flash page as user data to provide fast access and regular error correction power by itself, and other part of the ECC parity can be stored somewhere else and received only when regular decoding fails. A linking table can be used to locate any of the ECC parity that is not stored with the original codewords.

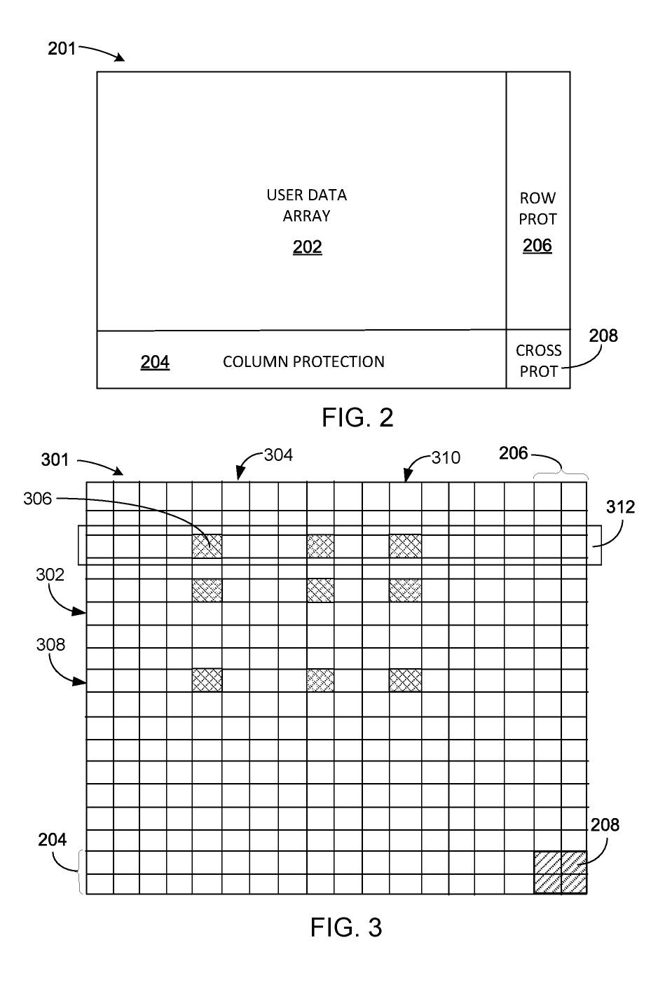

Referring now to FIG. 2, therein is shown an example architectural view of the multi-dimensional data protection mechanism 201 in an embodiment. The architectural view of the multi-dimensional data protection mechanism 201 depicts a user data array 202, a column protection 204, a row protection 206 and a cross protection 208.

The user data array 202 can be a memory segment or register array used for mapping the user data block 107 of FIG. 1 to be encoded or decoded. By way of an example the user data block 107 is shown to be 512 Bytes in the user data block 107 arranged into a 2-dimensional data protection mechanism as a 64-by-64 bits array. It is understood that the multi-dimensional data protection mechanism 201 can be of any size and can include additional instances of the user data array 202, the column protection 204, the row protection 206, and the cross protection 208 configured in parallel memory segments or register arrays to support additional embodiments. The multi-dimensional data protection mechanism 201 can instantiate as many of the additional instances of the user data array 202, the column protection 204, the row protection 206, and the cross protection 208 as is required to meet the performance requirements of the data storage system 101 of FIG. 1.

By way of the example, the column protection 204 can encode each column with systematic protection code parity, such as a BCH code, LDPC code, RS code, RAID parity, BSPP soft bit flipping, or a combination thereof. The column protection 204 is formed by appending the protection code parity at the end of each column. The row protection 206 is formed by appending the protection code parity at the end of each row. The sizes of the row protection 204 and the column protection 206 depend on the code rate of protection code codes used. The row protection 204, the column protection 206, and the cross protection 208 can be co-resident with the user data array 202 or they can be implemented separately. In an embodiment with a separate location for the row protection 204, the column protection 206, and the cross protection 208, a linking table can be used to link the contents of the user data array 202.

The encode-decode module 170 of FIG. 1 can encode rows first, columns first, or both concurrently, with hardware assist. The encode-decode module 170 will generate the exact same 2D-BCH codewords at the end without regard to which of the column protection 204 or row protection 206 is first executed. The cross protection 208 can either be generated from the column protection 204 or from row protection 206. Since BCH codes are linear codes, either way will give the exact same values of the cross protection 208. It is understood that the cross protection 208 can provide error correction for the column protection 204 or for the row protection 206 as necessary.

It is understood that the cross protection 208 can provide error correction for the column protection 204 or for the row protection 206 if they are read with errors. If the column protection 204, for the row protection 206, cross protection 208, or a combination thereof is stored in a location separate from the codewords of the user data array 202, the locations can be linked through a linking table or a logical to physical table stored in non-volatile memory.

Referring now to FIG. 3, therein is shown an exemplary stopping set 301 of error bits 306 in a user data array 202 of FIG. 2 in an embodiment. The stopping set 301 can occur when the number of error bits 306 in row code words 302 and column code words 304 exceeds a correctable limit.

The row code words 302 include the contents of the user data block 107 of FIG. 1 that is loaded into a contiguous row of the user data array 202 of FIG. 2 and the corresponding contents of the row protection 206. The column code words 304 include the contents of the user data block 107 of FIG. 1 that is loaded into a contiguous column of the user data array 202 and the corresponding contents of the column protection 204.

By way of the above example, when decoding the 2D-BCH codes representing the user data block 107 of FIG. 1, all the row code words 302 can be decoded in parallel, then all the column code words 304 are decoded in parallel. In some embodiments, the column code words 304 can be decoded first and then the row code words 302. After decoding both the row code words 302 and the column code words 304, one decoding iteration is completed. The decoding iterations can continue until either the user data block 107 has been decoded successfully or the pre-defined maximum number of iterations has been reached.

In some embodiments, when code rate is high, each of the row code words 302 or the column code words 304 can only correct a small number of error bits 306, which can be denoted by t. It is understood that the iterations can correct most errors, an error floor phenomenon can be demonstrated in 2D-BCH when t is relatively small compared to the code length. An error floor can be described as an abrupt change in the error correction performance of an embodiment of a 2D-BCH decoder in high signal-to-noise (SNR) regions.

The error floor occurs when the number of the error bits 306 exceeds the number t in both the row code words 302 and the column code words 304 that intersect at the error bits 306. By way of an example, for a 2D-BCH code with the row code words 302 and the column code words 304 both have t=2, when 9 error bits are located in the intersection of 3 rows and 3 columns, as shown in FIG. 3. The position of the error bits 306 can represent the error floor because the row code words 302 and the column code words 304 would be uncorrectable in such setting while any 9 error bits located in 4 or more columns/rows can be easily corrected. This condition can be called the stopping set 301 because iterative decoding of the row code words 302 and the column code words 304 cannot resolve the error bits 306 under normal processing.

After the encode-decode module 170 of FIG. 1 has completed a specific number of decoding iterations, if the encode-decode module 170 detects that the number of uncorrectable rows 308, eᵣ, is less than twice of the limit of the number of correctable row errors, tᵣ, i.e.:

eᵣ<2tᵣ Equation 1

And if the encode-decode module 170 detects that the number of uncorrectable columns 310, e_{c}, is less than twice of the limit of the number of correctable column errors, t_{c}, i.e.:

e_{c}<2t_{c} Equation 2

Then, the encode-decode module 170 can flip all the error bits 306 that are located in the intersection of uncorrectable rows 308 and uncorrectable columns 310. Hence, there are a total eᵣ·e_{c} bits are flipped by changing states from 0 to 1 or 1 to 0. Then, continue normal decoding iterations. This can make one or more of the uncorrectable rows 308, or the uncorrectable columns 310, correctable.

In an embodiment, a single one of the uncorrectable rows 308 or the uncorrectable columns 310 can be selected as a selected error code word 312 for individualized processing. It is understood that the selected error code word 312 can only be one of the uncorrectable rows 308 or the uncorrectable columns 310. Since the user data array 202 provides complete protection codewords for the row code words 302 and the column code words 304, either selection of a single one of the uncorrectable rows 308 or the uncorrectable columns 310 can provide a method to resolve the stopping set 301 by an embodiment as described below.

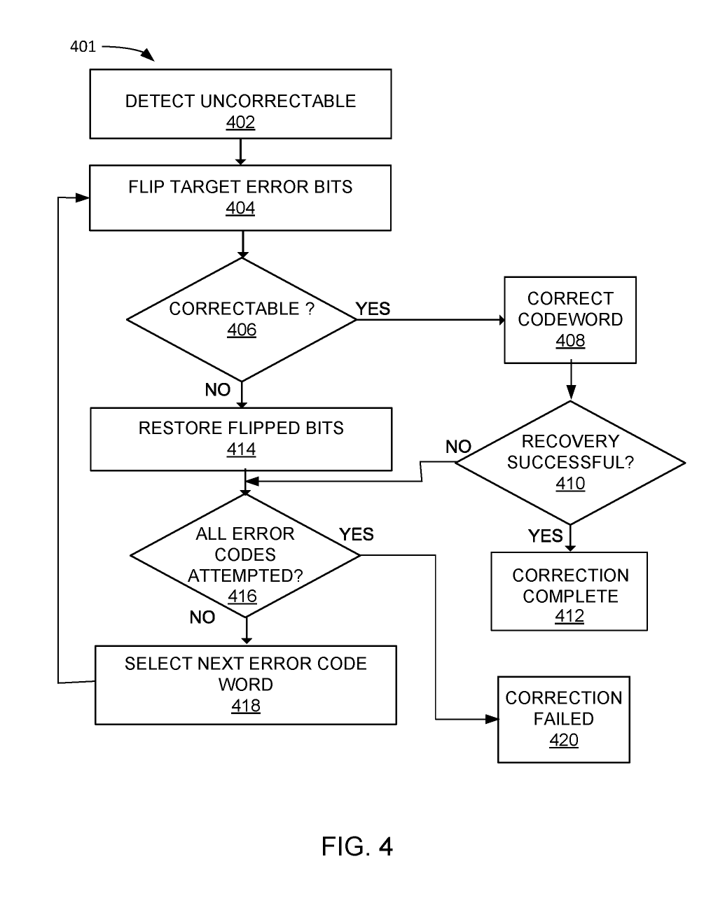

Referring now to FIG. 4, therein is shown a flow chart of an adaptive bit flipping algorithm 401 of the multi-dimensional data protection mechanism 100 in an embodiment. The adaptive bit flipping algorithm 401 of the multi-dimensional data protection mechanism 201 of FIG. 2 can be applied, by the encode-decode module 170, to the uncorrectable rows 308 of FIG. 3 or the uncorrectable columns 310 of FIG. 3 to significantly reduce the error floor by providing the multi-dimensional data protection mechanism 100 the ability of correcting some of the stopping sets.

By way of an example, if each of the row code words 302 of FIG. 3 can correct up to tᵣ of the error bits 306 of FIG. 3 and each of the column code words 304 of FIG. 3 can correct up to t_{c} of error bits 306, the following processes can reduce the error floor. An adaptive bit flipping algorithm can significantly reduce the error floor by providing the multi-dimensional data protection mechanism 100 the ability of correcting some of the stopping sets.

If the encode-decode module 170 detects that the uncorrectable columns 310, e_{c}, are not less than twice of the correctable column errors t_{c}, i.e.:

e_{c}≥2t_{c} Equation 3

And the uncorrectable rows 308, eᵣ, are not less than twice of the correctable row errors tᵣ, i.e.:

eᵣ≥2tᵣ Equation 4

The encode-decode module 170 can select a first of the uncorrectable rows 308, eᵣ or a first of the uncorrectable columns 310, e_{c} to start the adaptive bit flipping algorithm 401 as described below.

The adaptive bit flipping algorithm 401 shows a detect uncorrectable module 402, in which the encode-decode module 170 can detect the uncorrectable rows 308, eᵣ and the uncorrectable columns 310, e_{c} in the user data array 202 of FIG. 2. It is understood that the user data array 202 can include the user data block 107 of FIG. 1. The detect uncorrectable module 402 can pick a selected error code word 312 from the uncorrectable rows 308, eᵣ or the uncorrectable columns 310, e_{c} for a flip target error bits module 404.

The flip target error bits module 404 can flip some or all of the error bits 306 of FIG. 3 in the selected error code word 312. The error bits 306 can be flipped from 0 to 1 or from 1 to 0 depending on the current state. By flipping the error bits 306, it can be possible to correctly decode the selected error code word 312. It is understood that only one of either the uncorrectable rows 308, eᵣ or the uncorrectable columns 310, e_{c} can be the selected error code word 312 addressed by the flip target error bits module 404.

A verify correctable module 406 can determine whether the flip target error bits module 404 was successful in correcting the selected error code word 312. Some of the row code words 302 or the column code words 304 that were made correctable may have all of the error bits 306 corrected in the user data array 202 of FIG. 2 by a correct codeword module 408.

The correct codeword module 408 can correct all of the error bits 306 in the selected error code word 312 that was addressed by the flip target error bits module 404. Once the correct codeword module 408 has successfully corrected the selected error code word 312, an attempt can be made to correct all of the uncorrectable rows 308, eᵣ and the uncorrectable columns 310, e_{c} that still have the error bits 306.

A recovery successful module 410 can determine whether all of the uncorrectable rows 308, eᵣ or the uncorrectable columns 310, e_{c} are now corrected. If all of the error bits 306 are now corrected, a correction complete module 412 can approve the user data block 107 for transfer from the user data array 202. In case only the selected error code word 312 was successfully corrected, but more of the error bits 306 remain uncorrectable, a verify all codes attempted module 416 is activated.

If the verify correctable module 406 determines that the selected error code word 312 was not successfully corrected, a restore flipped bits module 414 can return the error bits 306 of the selected error code word 312 back to their original state. With the error bits 306 of the selected error code word 312 restored, the verify all codes attempted module 416 can determine whether each of the uncorrectable rows 308, eᵣ and the uncorrectable columns 310, e_{c} has been attempted as the selected error code word 312.

If not all of the uncorrectable rows 308, eᵣ or the uncorrectable columns 310, e_{c} has been attempted as the selected error code word 312, a select next error code word module 418 is activated. The select next error code word module 418 can target any of the remaining of the uncorrectable rows 308, eᵣ or the uncorrectable columns 310, e_{c} as the selected error code word 312.

The new selected error code word 312 can be returned to the flip target error bits module 404 for further processing. If all of the uncorrectable rows 308, eᵣ and the uncorrectable columns 310, e_{c} have been attempted, the correction failed module 420 can notify the host CPU 104 of FIG. 1 that the user data block 107 has uncorrectable errors.

Given that the occurrence of the stopping set 301 is extremely rare, the adaptive bit flipping algorithm 401 requires at most e_{c} or eᵣ iterations, which is very complex and latency affordable for practical implementation. The threshold of e_{c} or eᵣ to trigger the adaptive bit flipping algorithm 401 depends on the design decoding latency requirement.

It has been discovered that the adaptive bit flipping algorithm 401 can effectively correct the user data block 107 that would otherwise contain too many of the error bits 306 for a normal recovery algorithm. Since the adaptive bit flipping algorithm 401 can be implemented by hardware, software, or a combination thereof, it can be tuned to balance cost and execution time for different applications. The individual processing of the uncorrectable rows 308, eᵣ and the uncorrectable columns 310, e_{c} can significantly reduce the error floor and provide reliable error correction.

In an embodiment, the flip target error bits module 404 can utilize with a one-dimension single parity RAID system. The parity sector can be denoted by P and the data sectors with in a RAID stripe by Sᵢ, 0≤i≤N−1. Hence, we have:

P=Σᵢ₌₀^{N-1}Sᵢ Equation 5

Where the addition is a bit-wise XOR of the binary field. If the row code words 302 or the column code words 304 Sₜ of t-th sector failed and the corresponding row code words 302 and the column code words 304 in the remaining sectors in the RAID stripe are correctly decoded, the RAID recovery computes the following:

Sᵢ=Σ_{i≠t}S′ᵢ+P′ Equation 6

can directly recover the uncorrectable rows 308 or the uncorrectable columns 310, where the addition is in binary field (i.e., bit-wise XOR) and S′ᵢ and P′ are corrected codewords.

If there are more than one uncorrectable BCH codewords in a RAID stripe, we use bitwise RAID result to indicate the reliability of each bit. Define

X [symbol] Σᵢ₌₀^{N-1}S′ᵢ+P′ Equation 7

where the addition is in binary field (i.e., bit-wise XOR) and S′ᵢ and P′ are the row code words 302 and the column code words 304 after initial decoding. If X_{i,j}=1, then the corresponding bit of i-th row and j-th column in each RAID sector is unreliable; and if X_{i,j}=0, then the corresponding bit of i-th row and j-th column in each RAID sector is reliable.

Once the reliability of each bit has been determined, the flip target error bits module 404 can utilize the reliability information similarly to bit flipping with soft read. As an example, assume set Eᵣ is the set of the uncorrectable rows 308 and E_{c} be the set of the uncorrectable columns 310 after initial decoding. For the bit R_{i,j} of i-th row and j-th column where i ϵ Eᵣ and j ϵ E_{c}, if X_{i,j}=0, then R_{i,j}=1−R_{i,j} (flipped), otherwise it remains unchanged.

It has been discovered that the multi-dimensional data protection mechanism 201 of FIG. 2 having multiple units in parallel. This embodiment can be hardware based with firmware support to enhance overall performance of the decode and correction process. In other embodiments, the entire decode and correction process could be performed by software executing on the host CPU 104. The flexibility of the multi-dimensional data protection mechanism 201 can provide additional embodiments combining hardware assist to software execution as required to meet the design goals of the design target for the storage system 100 of FIG. 1.

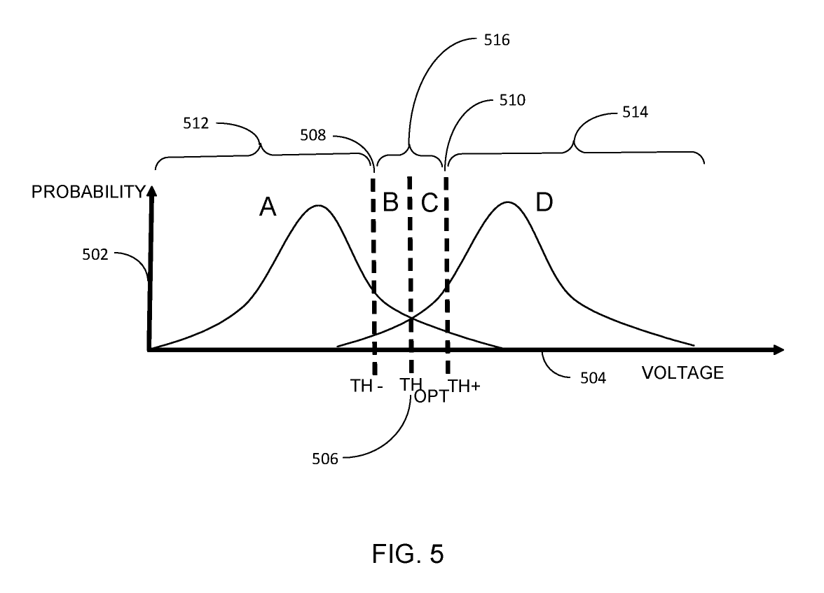

Referring now to FIG. 5, therein is shown a graph of a probability of data bit voltage across a voltage range. The graph of the probability 502 of the data bit voltage 504 shows the probability of cell voltage distributions of a FLASH memory cell (not shown) as an example of the mechanism for determining the confidence level of an individual data bit. It is understood that a similar mechanism can be utilized for successive readings of a magnetic bit with a physical offset from the track center.

The initial read of the data bit can be performed at an optimum threshold voltage (TH_{OPT}) 506. If an error is detected in the row code words 302 of FIG. 3, the row protection 206 of FIG. 2 can cause the storage engine 115 to re-read the user data block 107 of FIG. 1 using offsets, such as a lower threshold (TH−) 508 followed by reading with a higher threshold (TH+) 510.

If the data bit being analyzed provides the same level indication at the threshold TH_{OPT} 506 and the threshold TH− 508, the data bit is considered to be a logic 1 with high confidence indicated by confident 1 512. If the data bit being analyzed provides the same level indication at the threshold TH_{OPT} 506 and the threshold TH+ 510, the data bit is considered to be a logic 0 with high confidence indicated by confident 0 514. If however the data bit being analyzed provides the different level indication at the threshold TH− 508 and the threshold TH+ 510, the data bit is considered to be of low confidence whether it is detected as a logic 0 or a logic 1. This is indicated by a low confidence bit 516, which can be either a 0 or a 1.

By way of an example, let R⁺ and R⁻ be the data bit values with read threshold set to the threshold Th+ 510 and the threshold Th− 508, respectively. For readout of i-th data bit with the threshold Th+ 510, if a cell voltage falls into area “A”, “B”, or “C”, which has lower voltage than the threshold Th+ 510, then its corresponding bit value is the logic 1, i.e., R⁺(i)=1. If readout of i-th data bit falls into area “D” which has higher voltage than the threshold Th+ 510, then R⁺(i)=0.

Similarly, for the i-th readout with read threshold Th− 508, if a cell voltage falls into area “A” which has lower voltage than the threshold Th− 508, then its corresponding bit value 1, i.e., R⁻(i)=1. If the i-th readout with the threshold Th− 508 falls into area “B”, “C”, or “D” which has higher voltage than the threshold Th− 508, then , i.e., R⁻(i)=0.

It is understood that the analysis of magnetic media can be performed in a similar fashion by applying dimensional offsets from track center in order to emulate the threshold TH− 508 and the threshold TH+ 510. The data that is read on each of the re-read passes can be compared to determine the confidence level of the individual data bits.

It has been discovered that the confidence level of the individual data bits, of the user data block 107 that was detected to be in error, can be determined by comparing the resultant data bits at the nominal threshold TH_{OPT} 506 and at the offsets of the threshold TH− 508 and the threshold TH+ 510. Once the confidence level has been established as the soft read information, the flip target error bits module 404 of FIG. 4 can apply the soft read information to the selected error code word 312 of FIG. 3.

In an embodiment, the flip target error bits module 404 can utilize soft read information to determine the confidence level of the error bits 306 of FIG. 3 in the selected error code word 312. Flipping only the error bits 306 that have low confidence levels, provides an increased probability of being able to correct the selected error code word 312. The error bits that have a high confidence level can remain unflipped. This selective flipping of the error bits 306 can help increase the probability that a quick correction of the user data block 107 can be achieved.

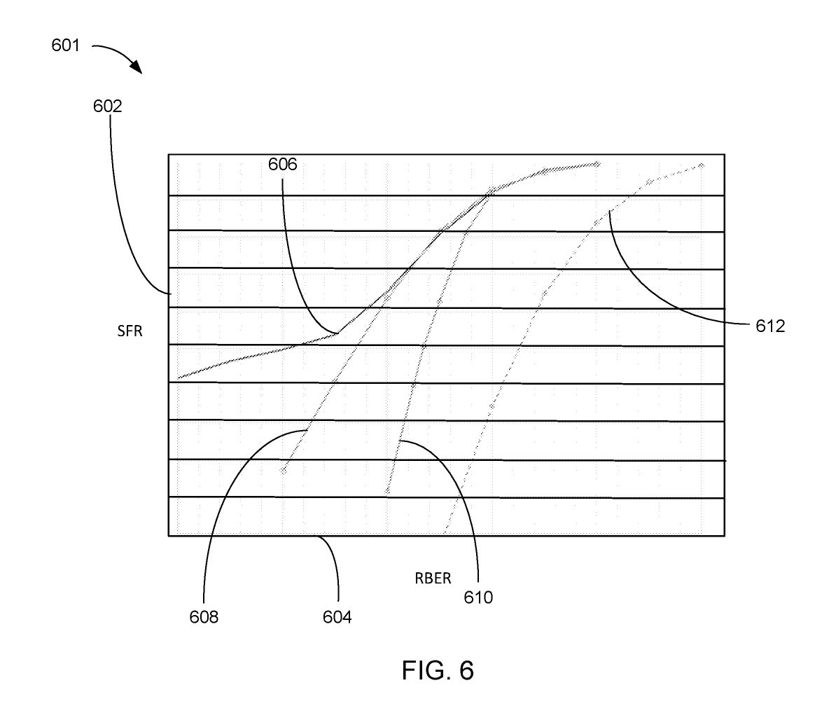

Referring now to FIG. 6, therein is shown a graph depicting an example improvement of the error floor as indicated by the raw bit error rate in an embodiment of the present invention. The graph depicts the gain of the adaptive bit flipping algorithm 401 of FIG. 1 of the multi-dimensional data protection mechanism 201 of FIG. 2 in terms of code word error rate along the y-axis 602 and the raw bit error rate of the media along the x-axis 604. There are four plots depicted on the graph, where the code length is 4K Bytes and the code rate is 0.845, as an example of possible improvements in the ability to correct data errors in the user data array 202 of FIG. 2.

A 2D-BCH 606 depicts the decoding performance with the column protection 204 of FIG. 2 and the row protection 206 of FIG. 2, such as the 2D-BCH error correction and coding scheme. This performance line acts as a baseline since this is the simplest form of the multi-dimensional data protection mechanism 201 to implement. The flat part of the 2D-BCH 606 is the aforementioned error floor.

A 2D-BCH with adaptive bit flipping 608 can be the process described as shown in FIG. 4, which utilizes the column protection 204, the row protection 206 of FIG. 2, and an embodiment of the flip target error bits module 404 of FIG. 4. The 2D-BCH with adaptive bit flipping 608 can provide an improvement in sector failure rate at the low end of the raw bit error rate.

A 2D-BCH with 15+1 RAID parity 610 can provide additional improvement in the mid and low end raw bit error rate which eliminates the error floor of the 2D-BCH 606 as well as speed advantages over traditional RAID processing. It has been demonstrated that performance provided by the 2D-BCH 606, the 2D-BCH with adaptive bit flipping 608, and the 2D-BCH with 15+1 RAID parity 610 can provide substantially similar performance above a mid-range raw bit error rate, while they can vary in implementation cost and speed of execution.

A 2D-BCH with soft read 612 can provide the best overall performance across the raw bit error rate. The 2D-BCH with soft read 612 allows the flip target error bits module 404 to selectively flip the error bits 306 that have low confidence. This can provide a substantial advantage for reliability and overall performance.

For illustrative purposes, the storage system 100 is described operating on the user data array 202 of FIG. 2, the column protection 204 of FIG. 2 and the row protection 206 of FIG. 2, independent of location. It is understood that the data storage system 101 of FIG. 1, the storage engine 115 of FIG. 1, the DAS devices 116 of FIG. 1, the network attached storage devices 122 of FIG. 1, and the encode-decode module 170 of FIG. 1 can provide the user data array 202, the column protection 204, the row protection 206, or a combination thereof. The user data array 202 can also represent the non-volatile memory 112, the memory devices 117, the local storage device 110, the direct attach storage devices 119, or a combination thereof.

The functions described in this application can be implemented as instructions stored on a non-transitory computer readable medium to be executed by the host central processing unit 104 of FIG. 1, the data storage system 101, the storage engine 115, the encode-decode module 170, or a combination thereof. The non-transitory computer medium can include the host memory of FIG. 1, the DAS devices 116 of FIG. 1, the network attached storage devices 122, the non-volatile memory 112, the memory devices 117, the local storage device 110, the direct attach storage devices 116, or a combination thereof. The non-transitory computer readable medium can include compact disk (CD), digital video disk (DVD), or universal serial bus (USB) flash memory devices. The non-transitory computer readable medium can be integrated as a part of the storage system 100 or installed as a removable portion of the storage system 100.

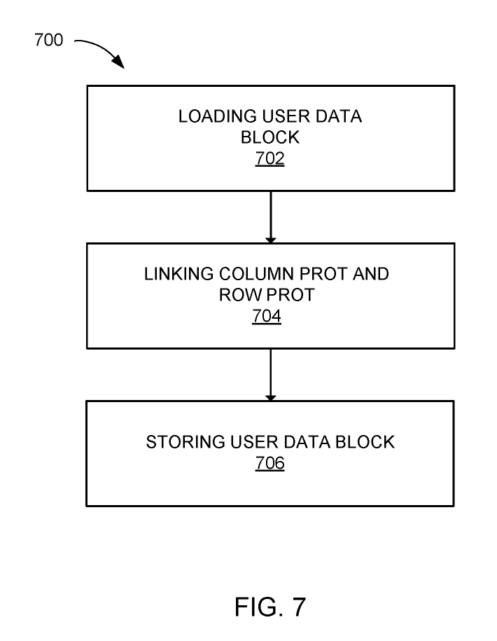

Referring now to FIG. 7, therein is shown a flow chart of a method 700 of operation of a storage system 100 in an embodiment of the present invention. The method 700 includes: loading a user data block in a user data array in a block 702; linking a column protection and a row protection with the user data array in a block 704; and storing the user data block linked to the column protection and the row protection in a block 706.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A storage system comprising:
a data storage system, configured to:
load a user data block in a user data array, and
link a column protection and a row protection with the user data array; and
a non-volatile storage device, coupled to the data storage system, configured to store the user data block linked to the column protection and the row protection.

2. The system as claimed in claim 1 wherein the data storage system is further configured to generate a column code word for the user data array and the column protection, and generate a row code word for the user data array and the row protection.

3. The system as claimed in claim 1 wherein the data storage system is further configured to detect an uncorrectable column from the user data array and the column protection.

4. The system as claimed in claim 1 wherein the data storage system is further configured to detect an uncorrectable row from the user data array and the row protection.

5. The system as claimed in claim 1 wherein the data storage system is further configured to perform an adaptive bit flipping algorithm on the user data block.

6. The system as claimed in claim 1 wherein the data storage system is further configured to detect a stopping set in the user data array.

7. The system as claimed in claim 1 wherein the data storage system is further configured to:
identify a low confidence bit among error bits;
flip the low confidence bit; and
correct the error bits with the low confidence bit flipped.

8. The system as claimed in claim 1 wherein the data storage system is further configured to load the user data block in the user data array and an additional instance of the user data array configured in parallel.

9. The system as claimed in claim 1 wherein the data storage system is further configured to identify a low confidence bit among error bits in the user data array for correcting the error bits.

10. The system as claimed in claim 1 wherein the data storage system is further configured to:
detect uncorrectable rows and uncorrectable columns in the user data array;
flip error bits in a selected error code word chosen from the uncorrectable rows or the uncorrectable columns; and
correct the error bits based on correcting the selected error code word.

11. A method of operation of a storage system comprising:
loading a user data block in a user data array;
linking a column protection and a row protection with the user data array; and
storing the user data block linked to the column protection and the row protection.

12. The method as claimed in claim 11 further comprising generating a column code word for the user data array and the column protection, and generating a row code word for the user data array and the row protection.

13. The method as claimed in claim 11 further comprising detecting an uncorrectable column from the user data array and the column protection.

14. The method as claimed in claim 11 further comprising detecting an uncorrectable row from the user data array and the row protection.

15. The method as claimed in claim 11 further comprising performing an adaptive bit flipping algorithm on the user data block.

16. The method as claimed in claim 11 further comprising detecting a stopping set in the user data array.

17. The method as claimed in claim 11 further comprising:
identifying a low confidence bit among error bits,
flipping the low confidence bit, and
correcting the error bits with the low confidence bit flipped.

18. The method as claimed in claim 11 further comprising loading the user data block in the user data array and an additional instance of the user data array configured in parallel.

19. The method as claimed in claim 11 further comprising identifying a low confidence bit among error bits in the user data array for correcting the error bits.

20. The method as claimed in claim 11 further comprising:
detecting uncorrectable rows and uncorrectable columns in the user data array;
flipping error bits in a selected error code word chosen from the uncorrectable rows or the uncorrectable columns; and
correcting the error bits based on correcting the selected error code word.

21. A non-transitory computer readable medium including instructions for execution, the medium comprising:
loading a user data block in a user data array;
linking a column protection and a row protection with the user data array; and
storing the user data block linked to the column protection and the row protection.

22. The medium as claimed in claim 21 further comprising generating a column code word for the user data array and the column protection, and generating a row code word for the user data array and the row protection.

23. The medium as claimed in claim 21 further comprising detecting an uncorrectable column from the user data array and the column protection.

24. The medium as claimed in claim 21 further comprising detecting an uncorrectable row from the user data array and the row protection.

25. The medium as claimed in claim 21 further comprising performing an adaptive bit flipping algorithm on the user data block.

26. The medium as claimed in claim 21 further comprising detecting a stopping set in the user data array.

27. The medium as claimed in claim 21 further comprising:
identifying a low confidence bit among error bits,
flipping the low confidence bit, and
correcting the error bits with the low confidence bit flipped

28. The medium as claimed in claim 21 further comprising loading the user data block in the user data array and an additional instance of the user data array configured in parallel.

29. The medium as claimed in claim 21 further comprising identifying a low confidence bit among error bits in the user data array for correcting the error bits.

30. The medium as claimed in claim 21 further comprising:
detecting uncorrectable rows and uncorrectable columns in the user data array;
flipping error bits in a selected error code word chosen from the uncorrectable rows or the uncorrectable columns; and
executing a correct code word module to correct all of the error bits based on correcting the selected error code word.
